(19) United States
(12) Patent Application Publication
(10) Pub. No.: US 2010/0140508 A1
(43) Pub. Date: Jun. 10, 2010

(54) COATED GRAPHITE LINERS

(76) Inventors: Julian G. Blake, Gloucester, MA (US); Dale K. Stone, Lynnfield, MA (US); Lyudmila Stone, Lynnfield, MA (US)

Correspondence Address: Nields, Lemack & Frame, LLC, 176 E. MAIN STREET, SUITE 5, WESTBOROUGH, MA, 01581, US

(21) Appl. No.: 12/328,307

(22) Filed: Dec. 4, 2008

(51) Int. Cl. H01J 37/08

(52) U.S. Cl. 250/492.21

(57) ABSTRACT

Liner elements designed to protect the components located in the beam line are disclosed. These liner elements, preferably constructed from graphite, are coated with a non-metal material, such as silicon, silicon carbide or diamond like carbon. These coatings significantly reduce the loose particles created by the liner. Therefore, following preventative maintenance, the ion implantation system can return to normal operation sooner. A method of providing preventative maintenance for an ion implanter is also disclosed, whereby used liners are cleaned and recoated before being used again.

### BACKGROUND OF THE INVENTION

Ion implanters are commonly used in the production of semiconductor wafers. An ion source is used to create an ion beam, which is then directed toward the wafer. As the ions strike the wafer, they dope a particular region of the wafer. The configuration of doped regions defines their functionality, and through the use of conductive interconnects, these wafers can be transformed into complex circuits.

A block diagram of a representative ion implanter 1 is shown in FIG. 1. Power supply 2 supplies the required energy to the ion source 3 to enable the generation of ions. An ion source 3 generates ions of a desired species. In some embodiments, these species are mono-atoms, which are best suited for high-energy implant applications. In other embodiments, these species are molecules, which are better suited for low-energy implant applications. The ion source 3 has an aperture through which ions can pass. These ions are attracted to and through the aperture by electrodes 4. These ions are formed into a beam 95, which then passes through a mass analyzer 6. The mass analyzer 6, having a resolving aperture, is used to remove unwanted components from the ion beam, resulting in an ion beam having the desired energy and mass characteristics passing through resolving aperture. Ions of the desired species then pass through a deceleration stage 8, which may include one or more electrodes. The output of the deceleration stage is a diverging ion beam.

A corrector magnet 13 is adapted to deflect the divergent ion beam into a set of beamlets having substantially parallel trajectories. Preferably, the corrector magnet 13 comprises a magnet coil and magnetic pole pieces that are spaced apart to form a gap, through which the ion beamlets pass. The coil is energized so as to create a magnetic field within the gap, which deflects the ion beamlets in accordance with the strength and direction of the applied magnetic field. The magnetic field is adjusted by varying the current through the magnet coil. Alternatively, other structures, such as parallelizing lenses, can also be utilized to perform this function.

Following the corrector magnet 13, the ribbon beam is targeted toward the workpiece. In some embodiments, a second deceleration stage 11 may be added. The workpiece is attached to a workpiece support 15. The workpiece support 15 provides a variety of degrees of movement for various implant applications.

A block diagram of a second representative ion implanter 100, typically used for low energy implants, is shown in FIG. 2. An ion source 110 generates ions of a desired species. In some embodiments, these species are atomic ions, which are best suited for high implant energies. In other embodiments, these species are molecular ions, which are better suited for low implant energies. These ions are formed into a beam, which then passes through a source filter 120. The source filter is preferably located near the ion source. The ions within the beam are accelerated/decelerated in column 130 to the desired energy level. A mass analyzer magnet 140, having an aperture 145, is used to remove unwanted components from the ion beam, resulting in an ion beam 150 having the desired energy and mass characteristics passing through resolving aperture 145.

In certain embodiments, the ion beam 150 is a spot beam. In this scenario, the ion beam passes through a scanner 160, which can be either an electrostatic or magnetic scanner, which deflects the ion beam 150 to produce a scanned beam 155-157. In certain embodiments, the scanner 160 comprises separated scan plates in communication with a scan generator. The scan generator creates a scan voltage waveform, such as a sine, sawtooth or triangle waveform having amplitude and frequency components, which is applied to the scan plates. In a preferred embodiment, the scanning waveform is typically very close to being a triangle wave (constant slope), so as to leave the scanned beam at every position for nearly the same amount of time. Deviations from the triangle are used to make the beam uniform. The resultant electric field causes the ion beam to diverge as shown in FIG. 1.

In an alternate embodiment, the ion beam 150 is a ribbon beam. In such an embodiment, there is no need for a scanner, so the ribbon beam is already properly shaped.

An angle corrector 170 is adapted to deflect the divergent ion beamlets 155-157 into a set of beamlets having substantially parallel trajectories. Preferably, the angle corrector 170 comprises a magnet coil and magnetic pole pieces that are spaced apart to form a gap, through which the ion beamlets pass. The coil is energized so as to create a magnetic field within the gap, which deflects the ion beamlets in accordance with the strength and direction of the applied magnetic field. The magnetic field is adjusted by varying the current through the magnet coil. Alternatively, other structures, such as parallelizing lenses, can also be utilized to perform this function.

Following the angle corrector 170, the scanned beam is targeted toward the workpiece 175. The workpiece is attached to a workpiece support. The workpiece support provides a variety of degrees of movement.

The components that constitute the ion implanter 1, 100 are referred to as beam line components, and can be subjected to degradation due to the harsh operating conditions. These beam line components can be subject to erosion and particle buildup. To protect these metal components from introducing contamination onto the workpiece, it is common to protect these components with liners, typically made from materials such as graphite, silicon coated aluminum, plasma treated Kapton, and silicon carbide. These liners therefore experience these harsh conditions, and therefore become susceptible to erosion and particle buildup.

To remedy this, the liners are typically periodically cleaned during a preventative maintenance cycle. However, this cleaning process often causes a large number of particles to be created on the liners. These particles can then contaminate workpieces being implanted once normal operation is resumed.

However, while this cleaning process causes particles to be created, it is an essential step in the ion implantation process and cannot be eliminated. Therefore, it becomes necessary to contend with these particles. In some embodiments, the number of particles is sufficiently small so as not to contaminate the workpiece. In other embodiments, it is necessary to pre-treat the liners by implanting many non-functional workpieces, until the unwanted particle count has been sufficiently reduced.

It would be advantageous to develop a liner for an ion implant system which does not require this pre-treatment. Such a liner would reduce downtime, and therefore enhance the efficiency of the implanter.

### SUMMARY OF THE INVENTION

The problems of the prior art are addressed by the present disclosure, which describes liner elements designed to protect the components located in the beam line and also not emit particles after cleaning.

The liner elements, preferably constructed from graphite, are coated with a semi-insulating material, such as silicon, silicon carbide or diamond like carbon. These coatings significantly reduce the loose particles created by the liner.

In another embodiment, a method of providing preventative maintenance for an ion implanter is disclosed. This method involves the removal of used liners, and their replacement with freshly coated liners. The removed liners are then cleaned and re-coated and made available for later use.

### BRIEF DESCRIPTION OF THE DRAWINGS

FIG. 1 illustrates a block diagram of a representative ion implanter;

FIG. 2 illustrates a block diagram of a second representative ion implanter;

FIG. 3 shows a cross section of a coated liner elements; and

FIG. 4 is a flow chart illustrating a preventative maintenance process.

### DETAILED DESCRIPTION OF THE INVENTION

As stated above, liners, preferably made from graphite, are used to cover and protect components located in the beam path. Graphite liners are traditionally manufactured as follows. The individual liners are machined from a large piece of graphite. This machining step creates liners of the desired size and shape. However, the cutting process results in a large number of particles, such as loose graphite and metal from the cutting blade. These cut pieces are then purified to remove any residue left by the cutting surface. This purification typically takes place in a furnace at elevated temperatures with halogen gas, such as chlorine. The purified liners are then removed and ready for use in an ion implanter. Liners are attached to the beam line components typically by using a variety of mechanical fasteners.

Once installed, these liners are subjects to two distinct phenomena that cause damage to them. First, the ions from the beam itself tend to pull individual carbon atoms away from the liner. Those atoms near the surface are most susceptible to being stripped from the liner. Over time, the liners lose a measurable amount of material. As this process continues, the liners may become too thin to retain their ability to shield and protect the underlying components and therefore must be discarded.

The second phenomenon that occurs is particle build up. As the ion beam strikes surfaces, such as the workpiece, it causes atoms to be sputtered from that surface. These atoms then deposit themselves on other surfaces, such as the graphite liners. For example, workpieces, such as semiconductor wafers, are coated with photoresist material. This material sputters when exposed to the ion beam. This sputtered material eventually builds up on other surfaces, such as the liners. When a sufficient amount of material has built up, the liners must be cleaned.

Cleaning liners is a caustic process. Typically, the liner is subjected to slurry blasting, where a slurry of abrasive material is directed toward the liners at high velocity. This slurry successfully removes the particle build up, but leaves many particles on the liner. It is then commonplace to subject the liner to a second cleaning step, such as dry cleaning or ultrasonic cleaning. This second step removes the residue left by the slurry blasting. However, this two-step cleaning process causes some of the carbon atoms near the surface of the liner to be loose, and easily removed.

After the cleaning process is completed, the normal ion implantation process can resume. Because of the loose material on the liners, particles are removed from the liners during the ion implant process, with some being implanted into the workpiece. In some applications, this amount of contamination is acceptable, and there is no harm caused by these unwanted particles. However, in other applications, such as small geometries or complex semiconductor devices, the implantation of these unwanted particles is detrimental to the functionality and performance of the device.

In such applications, it is necessary to eliminate these loose particles. Typically, this is achieved by pre-treating the ion implanter. In other words, unusable, or “dummy” workpieces are implanted. The number of “dummy” workpieces used, and therefore the time required for this process, is determined based on the design tolerance to these unwanted particles. Those applications with very small geometries may require 500-3000 “dummy” wafers to be implanted before the contamination is sufficiently low. This pre-treatment consumes valuable workpieces, which are then discarded. More importantly, it effectively reduces the operational time of the ion implanter. Thus, this pre-treatment process further extends a preventative maintenance cycle.

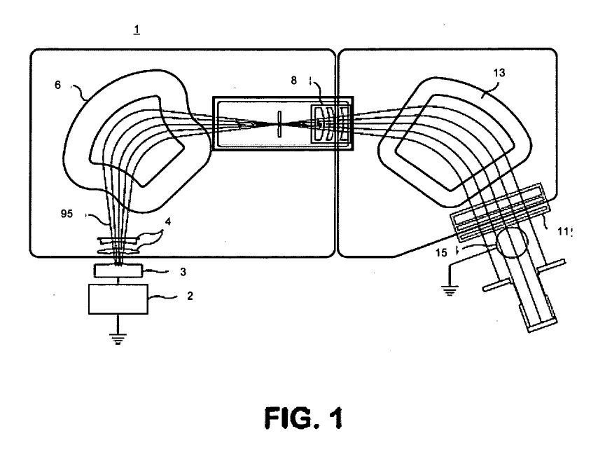

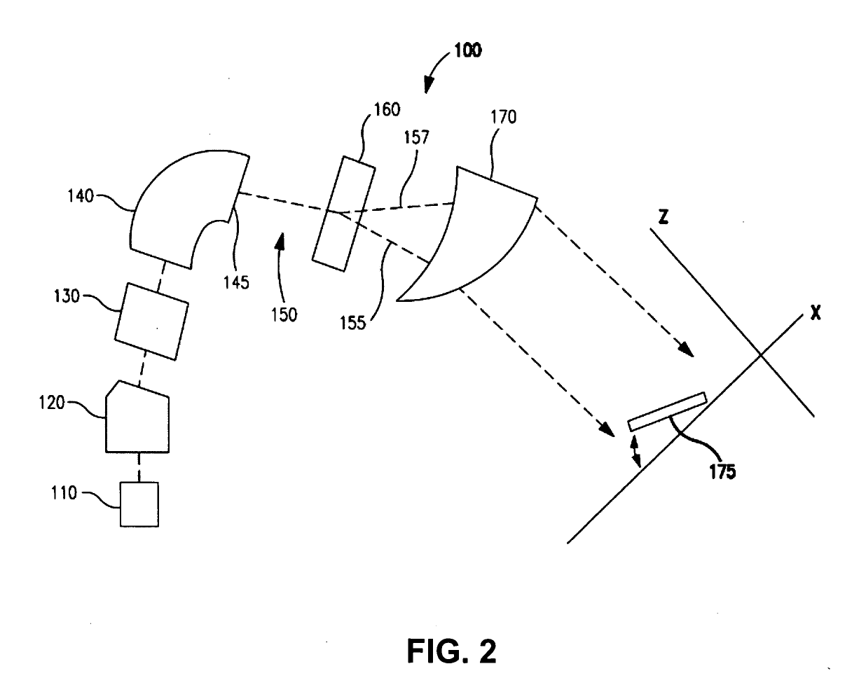

The liners that are used with beam line components in the line of sight of the workpiece contribute the majority of particles to the contaminated workpiece. These components include the corrector magnet 13 and second deceleration stage 11(as shown in FIG. 1) and the angle corrector 170 (as shown in FIG. 2). Eliminating the loose particles, specifically on these components, would significantly reduce or perhaps eliminate the need for pre-treatment.

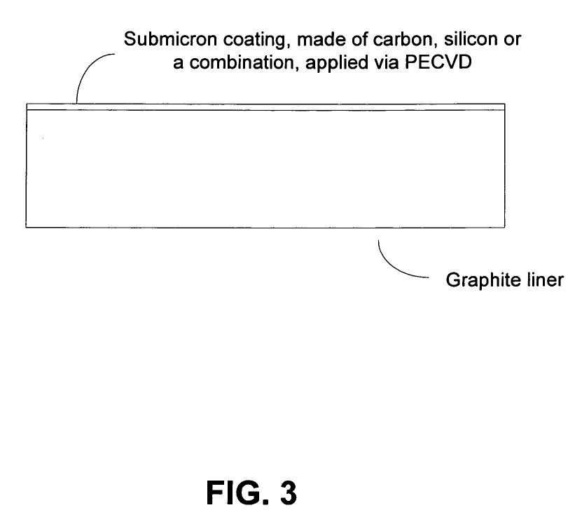

To eliminate these loose particles, the graphite liners may be coated with a thin layer of a material, such as a non-metal containing silicon carbide, silicon, or diamond like carbon. In some embodiments, this coating is applied using plasma enhanced chemical vapor deposition (PECVD). In other embodiments, physical vapor deposition (PVD) or chemical vapor deposition (CVD) is used. In the case of silicon carbide, a carbon-based gas, such as methane is mixed with a silicon-based gas, such as silane or silicon tetrafluoride in a plasma chamber. These gasses are turned into plasma, and silicon carbide precipitates onto the graphite liner located within that chamber. For silicon coatings, silicon tetrafluoride is used as the source gas while for DLC, sources gases include hydrocarbons, such as methane and ethylene. In some embodiments, a submicron coating is applied, such as about 0.2 microns. This thin coating insures that the conductive properties of the graphite are not masked by the insulating properties of the applied coating. FIG. 3 shows a cross section of a coated graphite liner.

These specially coated liners can then be applied within the ion implanter 100, especially to beam line components with a line of sight to the workpiece.

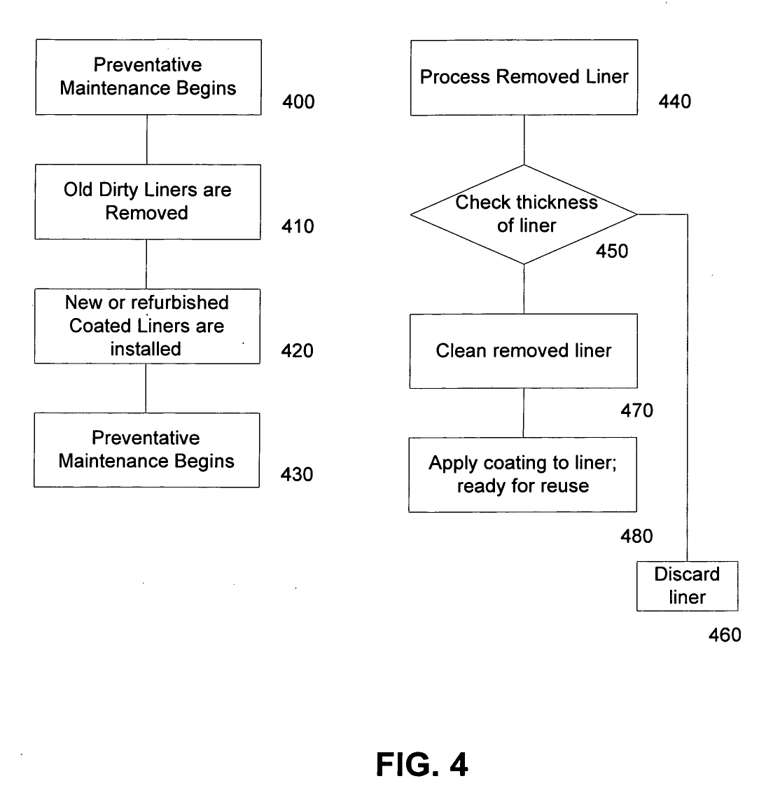

The special coating reduces the need to perform pre-treatment to remove unwanted particles. Based on this, a new preventative maintenance process can be performed. FIG. 4 shows a simple flowchart showing the preventative maintenance cycle, as it applies to liners. Preventative maintenance begins at step 400. The current dirty liners are removed from the components of the ion implanter, as shown in step 410. These removed liners will be described in more detail later in the process, starting at step 440. After the dirty liners have been removed, new or refurbished liners are applied to the beam line components, as shown in step 420. As stated above, those components with a line of sight to the workpiece must be lined with the specially coated liners. The other components can use either the specially coated liners or conventional liners. The actions within the ion implanter are now complete, and the implanter is ready for use, as shown in step 430. Since the specially coated liners do not emit unwanted particles, there is no need to pre-treat the ion implanter, as is currently done.

The removed liners are now processed, as shown in step 440. First, the thickness of the liner is checked in step 450. If sufficient material has been eroded from the liner, it is discarded, as shown in step 460. If the liner is still usable, it is first cleaned in step 470. This cleaning process can be the two-step process described above. After the liner is cleaned, it is placed in the plasma chamber and, using PECVD, coated with a thin layer of material, as shown in step 480. This coated liner can now be reused. For example, during the next preventative maintenance cycle, these refurbished liners can be applied to the beamline components in step 420.

While this disclosure has described specific embodiments disclosed above, it is obvious to one of ordinary skill in the art that many variations and modifications are possible. Accordingly, the embodiments presented in this disclosure are intended to be illustrative and not limiting. Various embodiments can be envisioned without departing from the spirit of the disclosure.

What is claimed is:

1. An ion implantation system comprising:
a. A plurality of beamline components to direct an ion beam to a workpiece; and
b. A liner applied to at least one of said beamline components, said liner comprising a coating applied to said liner prior to said liner's application to said beamline component.

2. The ion implantation system of claim 1, wherein said coating is selected from the group consisting of silicon carbide, silicon, and diamond like carbon.

3. The ion implantation system of claim 1, where said coating is applied during plasma enhanced chemical vapor deposition.

4. The ion implantation system of claim 1, where said coating is applied during chemical vapor deposition.

5. The ion implantation system of claim 1, where said coating is applied during physical vapor deposition.

6. The ion implantation system of claim 1, wherein said coating is less than 1 micron thick.

7. The ion implantation system of claim 1 wherein said liner comprises graphite.

8. The ion implantation system of claim 1 wherein said liner is applied to a beamline component having a line of sight to said workpiece.

9. A method of performing maintenance on an ion implantation system having a plurality of beamline components, at least one of said components having a liner, comprising:
a. Removing said liner from said component;
b. Replacing said liner with a new or refurbished liner having a coating applied to said liner prior to said liner's application to said beamline component; and
c. Applying said new or refurbished liner to said component.

10. The method of claim 9, wherein said removed liner is tested to determine whether it can be reused.

11. The method of claim 10, wherein said determination is based on the thickness of said removed liner.

12. The method of claim 9, wherein said removed liner is subjected to a cleaning process.

13. The method of claim 12, wherein, subsequent to said cleaning, a coating is applied to said cleaned removed liner.

14. The method of claim 13, wherein said coating is applied via plasma enhanced chemical vapor deposition.

15. The method of claim 13, wherein said coating is applied via chemical vapor deposition.

16. The method of claim 13, wherein said coating is applied via physical vapor deposition.

17. The method of claim 9, wherein said coating is selected from the group consisting of silicon carbide, silicon, and diamond like carbon.

18. The method of claim 9, wherein said coated liner is applied to a beamline component having a line of sight to said workpiece.
